(19) United States
(12) Patent Application Publication
(10) Pub. No.: US 2026/0066614 A1
(43) Pub. Date: Mar. 5, 2026

(54) LIGHT SOURCE HEAT DISSIPATION STRUCTURE AND LIGHT SOURCE DEVICE INCLUDING SAME

(71) Applicant: IROYAL TECHNOLOGY CORPORATION, New Taipei City (TW)

(72) Inventors: CHING-HO HUANG, New Taipei City (TW); CHUNG-CHIEH HUANG, New Taipei City (TW); YUNG-PING CHIA, Taoyuan City (TW)

(21) Appl. No.: 18/975,740

(22) Filed: Dec. 10, 2024

(30) Foreign Application Priority Data
Sep. 5, 2024 (TW) 113133686

(51) Int. Cl. H01S 5/024; H01S 5/02355

(52) U.S. Cl. CPC H01S 5/02469; H01S 5/02355

(57) ABSTRACT

Provided are a light source heat dissipation structure and a light source device including the same. The light source heat dissipation structure includes a light-emitting component and a carrying plate. The carrying plate has a carrying surface, and the light-emitting component is arranged on the carrying surface. A material of the carrying plate is at least a high-thermal-conductivity material with a thermal conductivity of 380 W/mK or more. The high-thermal-conductivity material forms a first region on the carrying surface, and the light-emitting component is arranged in contact with the first region.

### FIELD OF THE INVENTION

The disclosure relates to a heat dissipation structure, and in particular to a heat dissipation structure suitable for a light source device.

### BACKGROUND OF THE INVENTION

Advances in science and technology have made medical treatment no longer confined to specific locations. In other words, portable and mobile equipment is increasingly in demand in the fields of medical treatment and emergencies. However, due to its special conditions, it is difficult for some equipment to develop towards miniaturization or lightweight. For example, a light source or light box with high lumen output often needs to be equipped with a large heat dissipater, thus hindering the development of the light source or light box towards miniaturization and lightweight. However, the light source/light box with high lumen output provides sufficient lighting for medical treatment and emergencies. Therefore, how to meet the heat dissipation effectiveness and realize the miniaturization/lightweight of the equipment is a problem to be solved.

### SUMMARY OF THE INVENTION

The disclosure provides a light source heat dissipation structure, which has good heat dissipation effectiveness, high heat dissipation efficiency, and reliable light output.

The disclosure further provides a light source device, which has good heat dissipation effectiveness and high heat dissipation efficiency and can provide reliable light output.

In order to achieve one or all of the above objectives or other objectives, an embodiment of the disclosure provides a light source heat dissipation structure, including a light-emitting component and a carrying plate. The carrying plate has a carrying surface, and the light-emitting component is arranged on the carrying surface. A material of the carrying plate is at least a high-thermal-conductivity material with a thermal conductivity of 380 W/mK or more. The high-thermal-conductivity material forms a first region on the carrying surface, and the light-emitting component is arranged in contact with the first region.

In an embodiment of the disclosure, the high-thermal-conductivity material is red copper.

An embodiment of the disclosure further provides a light source device, including the light source heat dissipation structure, a heat dissipation member, and a box. The heat dissipation member is connected to the light source heat dissipation structure, and the box has a light exit hole. The light source heat dissipation structure and the heat dissipation member are arranged in the box, and light generated by the light-emitting component is suitable to exit through the light exit hole.

According to the disclosure, the carrying plate is made of the high-thermal-conductivity material, and the light-emitting component is arranged in contact with the carrying plate, so the light source heat dissipation structure has good heat dissipation effectiveness and efficiency. Thereby, a temperature range of the light-emitting component can be well controlled, which helps in providing reliable light output. The use of the high-thermal-conductivity material is beneficial to achieve good heat dissipation effect with a small volume, so as to further realize miniaturization and lightweight of the light source device.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic three-dimensional view of a light source heat dissipation structure of a first embodiment of the disclosure;

FIG. 2 is a schematic three-dimensional exploded view of the light source heat dissipation structure of the embodiment of FIG. 1;

FIG. 3 is a schematic three-dimensional exploded view of the embodiment of FIG. 1 from another angle;

FIG. 4 is a schematic top view of a carrying plate of the first embodiment of the disclosure;

FIG. 5 is a schematic sectional view of the embodiment of FIG. 4 taken along line A-A;

FIG. 6 is a schematic three-dimensional exploded view of a light source heat dissipation structure of a second embodiment of the disclosure;

FIG. 7 is a schematic three-dimensional exploded view of the embodiment of FIG. 6 from another angle;

FIG. 8 is a schematic top view of a carrying plate of the second embodiment of the disclosure;

FIG. 9 is a schematic sectional view of the embodiment of FIG. 8 taken along line BB;

FIG. 10 is a schematic three-dimensional view of a light source device of an embodiment of the disclosure;

FIG. 11 is a schematic exploded view of the embodiment of FIG. 10;

FIG. 12 is a schematic partial view of the embodiment of FIG. 11;

FIG. 13 is a schematic partial view of the embodiment of FIG. 12;

FIG. 14 is a schematic exploded view of the embodiment of FIG. 13;

FIG. 15 is a schematic view of the embodiment of FIG. 13 from another angle; and

FIG. 16 is a schematic partial view of a light source device of another embodiment of the disclosure.

### DETAILED DESCRIPTION OF PREFERRED EMBODIMENTS

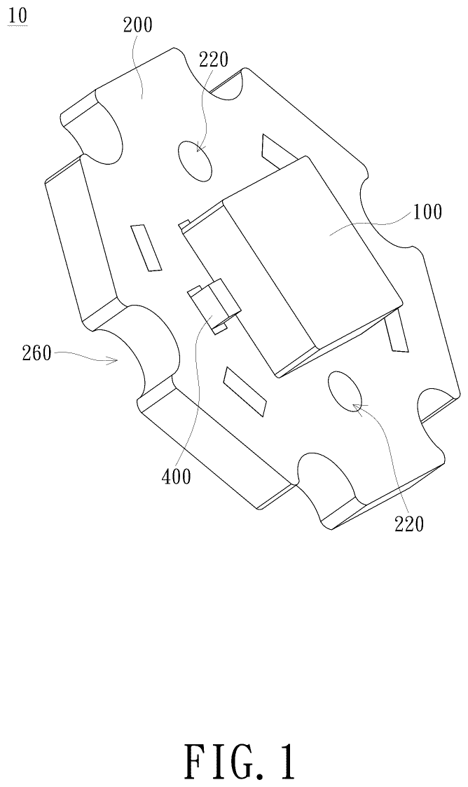

A light source heat dissipation structure of the disclosure, according to an embodiment shown in FIG. 1 to FIG. 3, including a light-emitting component 100 and a carrying plate 200. The carrying plate 200 has a carrying surface 201, and the light-emitting component 100 is arranged on the carrying surface 201. A material of the carrying plate 200 is at least a high-thermal-conductivity material, and the light-emitting component 100 may be further arranged in contact with a region on the carrying plate 200 with the high-thermal-conductivity material. In a preferred embodiment of the disclosure, the high-thermal-conductivity material is preferably red copper or other materials with a thermal conductivity, for example, 380 W/mK or more, and the light-emitting component 100 is usually a high heat generating source, so the arrangement of the light-emitting component 100 in contact with the carrying plate 200 is beneficial to rapid conduction and then dissipation of heat. In this embodiment of the disclosure, the light-emitting component 100 may be, for example, light-emitting diodes and laser diodes, and preferably white laser diodes. The light-emitting component 100 may be, for example, in the form of a TO-CAN package or other forms, such as a ceramic package.

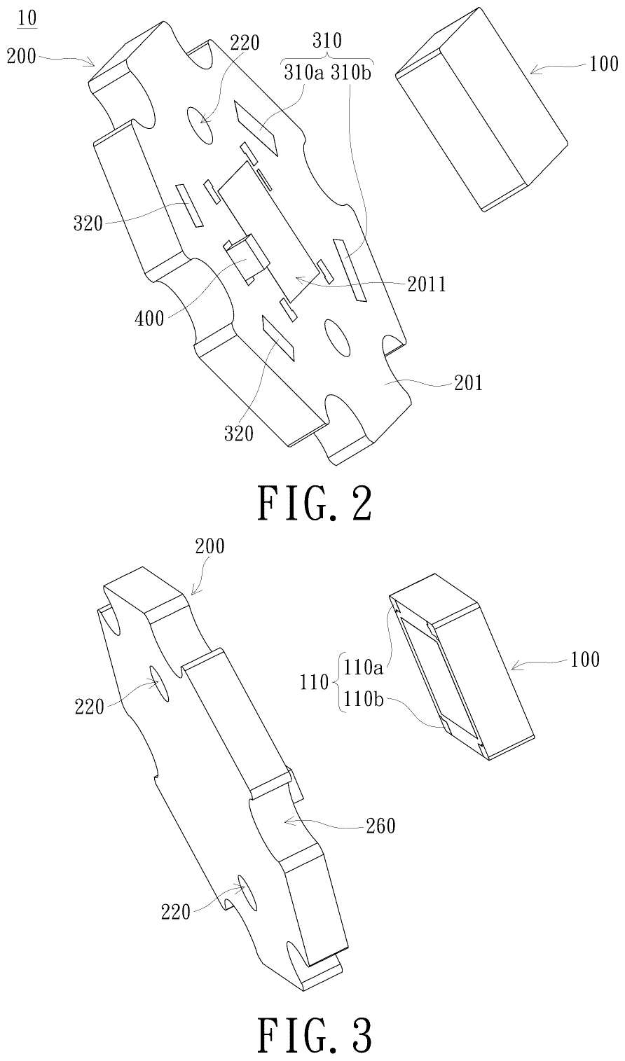

The high-thermal-conductivity material of the carrying plate 200 may further form a first region 2011 on the carrying surface 201, and the light-emitting component 100 is arranged in contact with the first region 2011. In a preferred embodiment of the disclosure, the first region 2011 is located in a middle of the carrying surface 201. The carrying surface 201 is preferably provided with pairs of electrodes, i.e., positive electrodes and negative electrodes, which are electrically connected to the light-emitting component 100. As shown in FIG. 2 to FIG. 3, the pairs of electrodes include a first pair of electrodes 310, and the light-emitting component 100 may have a pair of pins 110. The pair of pins 110 are preferably located at a bottom of the light-emitting component 100, where a side close to the carrying plate 200 is the bottom. The first pair of electrodes 310 are electrically connected to the light-emitting component 100 (for example, a positive electrode 310a is welded to a pin 110a, and a negative electrode 310b is welded to a pin 110b), and may also be electrically connected to an external circuit. The external circuit may be a circuit included in, for example, an electric power system and a control unit, and therefore, the light-emitting component 100 can be driven to emit light through the first pair of electrodes 310.

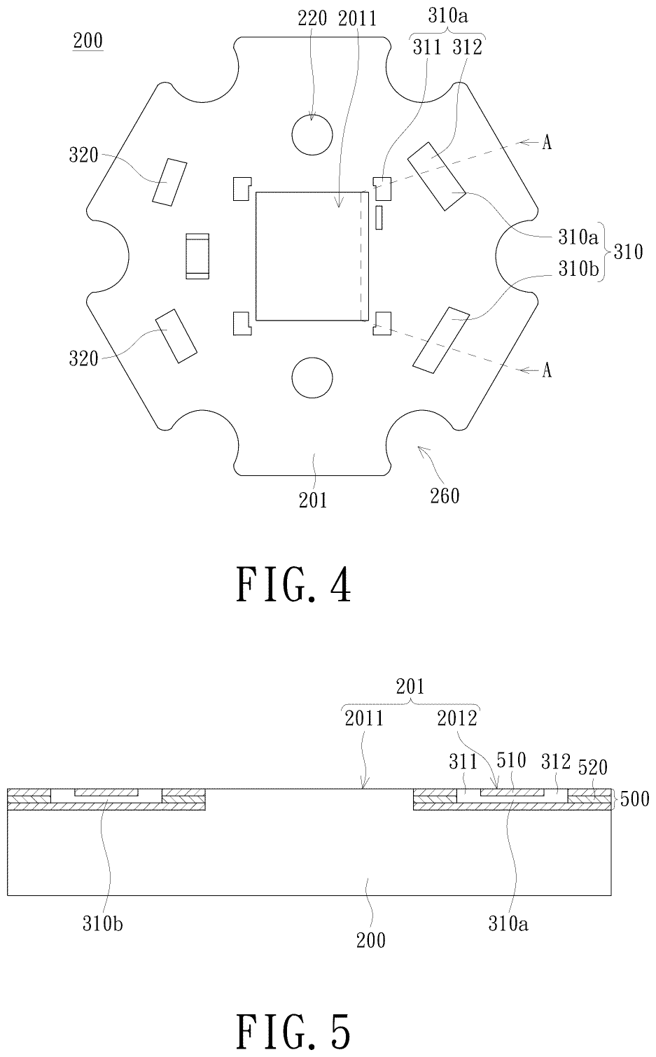

FIG. 4 and FIG. 5 respectively show a schematic top view of the carrying plate 200 and a schematic sectional view taken along line A-A in FIG. 4. As shown in FIG. 4 to FIG. 5, the light source heat dissipation structure 10 further includes a circuit board 500. The circuit board 500 may be arranged on the carrying surface 201. In addition to the first region 2011, the carrying surface 201 may further include a second region 2012 surrounding the first region 2011, and the circuit board 500 may be further arranged in the second region 2012. There is insulation provided between the circuit board 500 and the high-thermal-conductivity material of the carrying plate 200. Preferably, the circuit board 500 includes an insulating layer 510 and a wiring layer 520.

As shown in FIG. 5, the insulating layer 510 may be further arranged at a bottom of the circuit board 500 at a portion in contact with the carrying plate 200 and at a surface portion of the circuit board 500, and the wiring layer 520 may be located at an inner layer of the circuit board 500. That is, the insulating layer 510 and the wiring layer 520 may be stacked. Besides, the number of the insulating layers 510 and the wiring layers 520 is not limited to one. The circuit board 500 may be further electrically connected to the aforementioned external circuit. In a preferred embodiment of the disclosure, the first pair of electrodes 310 may be further arranged on the circuit board 500 and connected to the wiring layer 520. As shown in FIG. 5, for example, the light-emitting component 100 may be electrically connected to the first pair of electrodes 310, for example, by means of welding spots 311 where the pair of pins 110 are welded to inner sides of the first pair of electrodes 310, thereby being fixed to the carrying plate 200. Welding spots 312 on outer sides of the first pair of electrodes 310 may be configured to, for example, be welded to the external circuit. Therefore, the light-emitting component 100 may be electrically connected to, for example, the electric power system and the control unit through the circuit board 500.

The light source heat dissipation structure 10 may further include other components. In a preferred embodiment of the disclosure, the light source heat dissipation structure 10 further includes a thermally sensitive component 400, which may be configured to a temperature and a temperature change of the light-emitting component 100. In some embodiments of the disclosure, the thermally sensitive component 400 may be, for example, a thermistor, whose resistance value may change with the change of temperature and be fed back to the electric power system or the control unit, thereby affecting the work of the light-emitting component 100. For example, the thermally sensitive component 400 may prevent the light-emitting component 100 from approaching a temperature threshold, and preferably maintain the light-emitting component 100 in an appropriate temperature range, so as to provide reliable brightness output. The thermally sensitive component 400 may be further electrically connected to the pairs of electrodes on the carrying surface 201. As shown in FIG. 2 and FIG. 4, the pairs of electrodes may include a second pair of electrodes 320 electrically connected to the thermally sensitive component 400, for example, a positive electrode and a negative electrode are respectively welded to a pair of pins (not shown) of the thermally sensitive component 400. Besides, the thermally sensitive component 400 may also be fixed to the carrying plate 200 by welding.

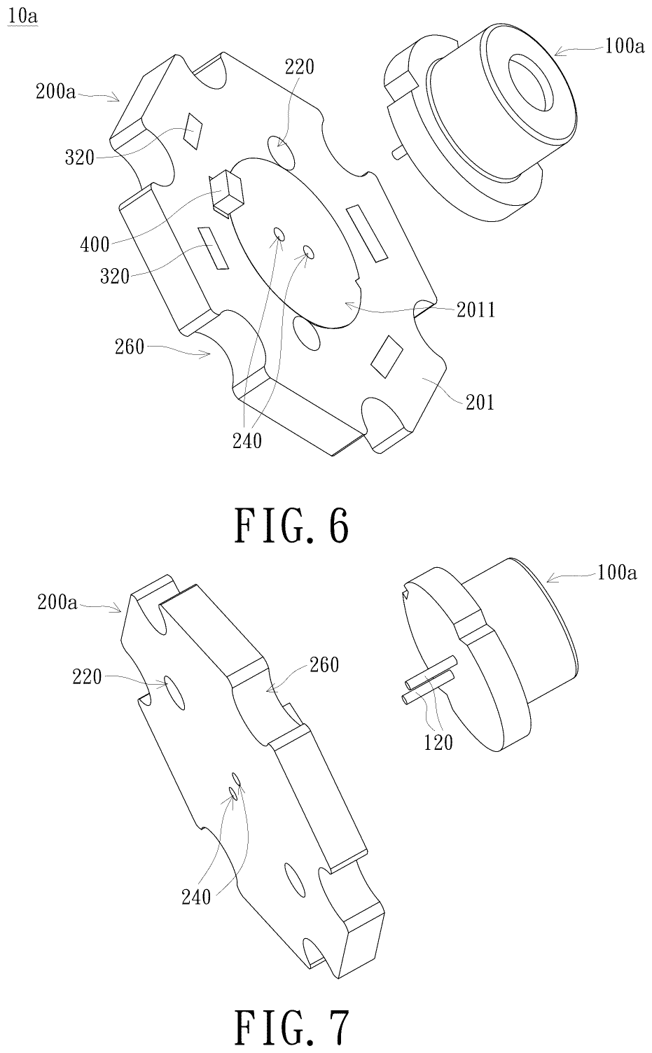

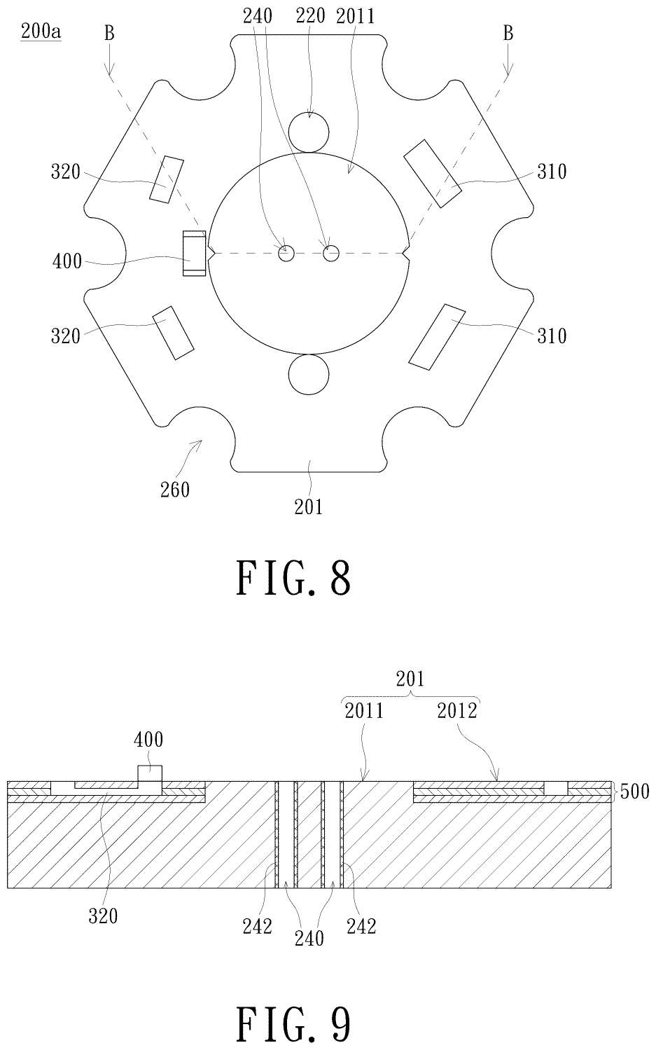

FIG. 6 to FIG. 9 show schematic views of a light source heat dissipation structure 10a of another embodiment of the disclosure. As shown in FIG. 6 to FIG. 9, the light source heat dissipation structure 10a includes a light-emitting component 100a and a carrying plate 200a. The difference from the above embodiment is that a bottom of the light-emitting component 100a has a pair of leaded pins 120, and a fixed seat 200a has a pair of socket holes 240 corresponding to the pair of leaded pins 120. As shown in FIG. 8 to FIG. 9, the pair of socket holes 240 run through the carrying plate 200a and are opened in the first region 2011 and two opposite sides of the carrying surface 201, and the pair of leaded pins 120 pass through the pair of socket holes 240 and can protrude from the opposite side of the carrying surface 201.

In this embodiment, the light-emitting component 100a may be electrically connected to, for example, an electric power system and a control unit through the pair of leaded pins 120. For example, the pair of leaded pins 120 can be electrically connected to an external circuit through wire welding, which can further make the light-emitting component 100a fixed to the carrying plate 200a. In addition, an insulating layer 242 is arranged in each of the pair of socket holes 240 so as to separate each of the pair of pins 240 from a wall of each of the socket holes 240. The wall of each of the socket holes 240 may include a region including the high-thermal-conductivity material. The light-emitting component 100a may be, for example, white laser diodes in a TO-CAN package.

As shown in FIG. 1 to FIG. 4 and FIG. 6 to FIG. 8, the light source heat dissipation structure 10 (10a) in the embodiments of the disclosure may further be formed with through holes 220 in the carrying plate 200 (200a). The through holes 220 run through the carrying plate 200 (200a) and are opened in the carrying surface 201 and two opposite sides of the carrying surface 201, and are suitable for wires to pass through. For example, when the pair of electrodes, such as the first pair of electrodes 310 and/or the second pair of electrodes 320, are welded to the external circuit through wires, then the wires may pass through the through holes 220 and are received therein, which is not limited thereto. The light source heat dissipation structure 10 (10a) in the embodiments of the disclosure may be further formed with notches 260 at edges of the carrying plate 200 (200a). The notches 260 may also be used for wires to pass through and be received therein.

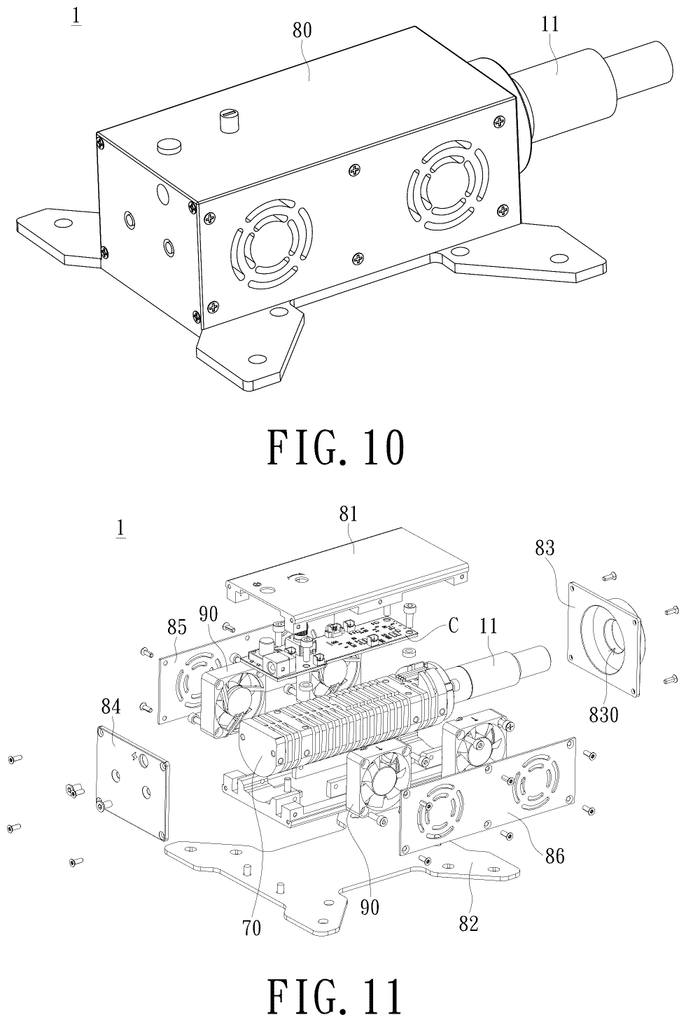

The disclosure further provides a light source device having good heat dissipation performance and reliable brightness output. FIG. 10 is a schematic three-dimensional view of the light source device of the embodiment of the disclosure, and FIG. 11 is an exploded view thereof. As shown in FIG. 10 to FIG. 11, the light source device 1 includes the light source heat dissipation structure 10 as described above, a heat dissipation member 70 and a box 80. The heat dissipation member 70 is formed of a material with good thermal conductivity, and preferably, has a groove structure, a fin structure or other structure that is beneficial to increase the heat dissipation area. The heat dissipation member 70 is connected to the light source heat dissipation structure 10, and both are arranged in the box 80.

As shown in FIG. 11, the box 80 of the light source device 1 may include a plurality of portions, such as upper and lower plate members 81, 82, front and rear plate members 83, 84, and left and right plate members 85, 86. The front plate member 83 may further have a light exit hole 830 for light to exit. A side of the light source heat dissipation structure 10 having the light-emitting component 100 faces the light exit hole 830. In a preferred embodiment of the disclosure, the light source device 1 further includes a tubular structure 11. The tubular structure 11 may be used for the light-emitting component 100 to be arranged therein, and is sleeved with the front plate member 83 and extends out of the box 80 via the light exit hole 830. An optical component, such as a lens, a mirror, a prism, or a combination thereof, may be further arranged in the tubular structure 11, which can be used for improving or changing light output of the light-emitting component 100, for example, used for adjusting a light exit angle. On the other hand, as shown in FIG. 10, the tubular structure 11 protrudes from the box 80, and thus, is suitable to serve as a connecting structure between the light source device 1 and other devices in some embodiments of the disclosure. For example, when the light source device 1 is used in the field of medical treatment, for example, to provide a light source for an endoscope, then the tubular structure 11 may be used to be connected to a base of the endoscope.

The light source device 1 may further include a fan 90 and a control board C, both of which are arranged in the box 80. The fan 90 is preferably arranged adjacent to the heat dissipation member 70, and the number of the fans is not limited to one. In some embodiments of the disclosure, the heat dissipation member 70 may be approximately in the shape of a long column, and the fans 90 may be substantially arranged along a height direction of the column of the heat dissipation member 70. In a preferred embodiment of the disclosure, the plurality of fans 90 are arranged on two opposite sides, such as the left side and the right side, of the heat dissipation member 70, and the fans 90 on each side are arranged along the height direction of the column. The box 80 may have openings corresponding to the fans 90, for example, in the left plate member 85 and the right plate member 86, for air convection and heat dissipation. The fans 90 may be fixed to the plate members 85, 86 and/or the heat dissipation member 70, for example, by screw locking, but are not limited thereto.

The control board C may be equivalent to the aforementioned control unit or may perform all or part of functions of the aforementioned control unit. The aforementioned electric power system may be, for example, a DC power supply, an AC power supply, a switched power supply or a combination thereof. In an embodiment of the disclosure, the control board C in the box 80 may preferably be arranged close to the upper plate member 81, the lower plate member 82, the left plate member 85 or the right plate member 86, and electrically connected to the light-emitting component 100, the thermally sensitive component 400 and the electric power system. By being electrically connected to the light-emitting component 100, the control board C can control the light-emitting component 100 to emit light, for example, control the light-emitting component 100 to emit light by transmitting electric power and controlling signals, and make the light-emitting component 100 have a different light-emitting brightness and a variable light-emitting frequency. For example, the control board C may, for example, lower the current supply to reduce the light-emitting brightness, or increase the current supply to improve the light-emitting brightness; and may, for example, control the power supply to be continuous or non-continuous, so that the light-emitting component 100 can emit light, for example, continuously or intermittently. By being electrically connected to the thermally sensitive component 400, the control board C can receive temperature-related signals and react. For example, the control board C can lower or limit, for example, the current supply after receiving the feedback from the thermally sensitive component 400, so as to avoid a continuous temperature rise of the light-emitting component 100 and/or maintain the light-emitting component 100 in an appropriate temperature range and have reliable light output.

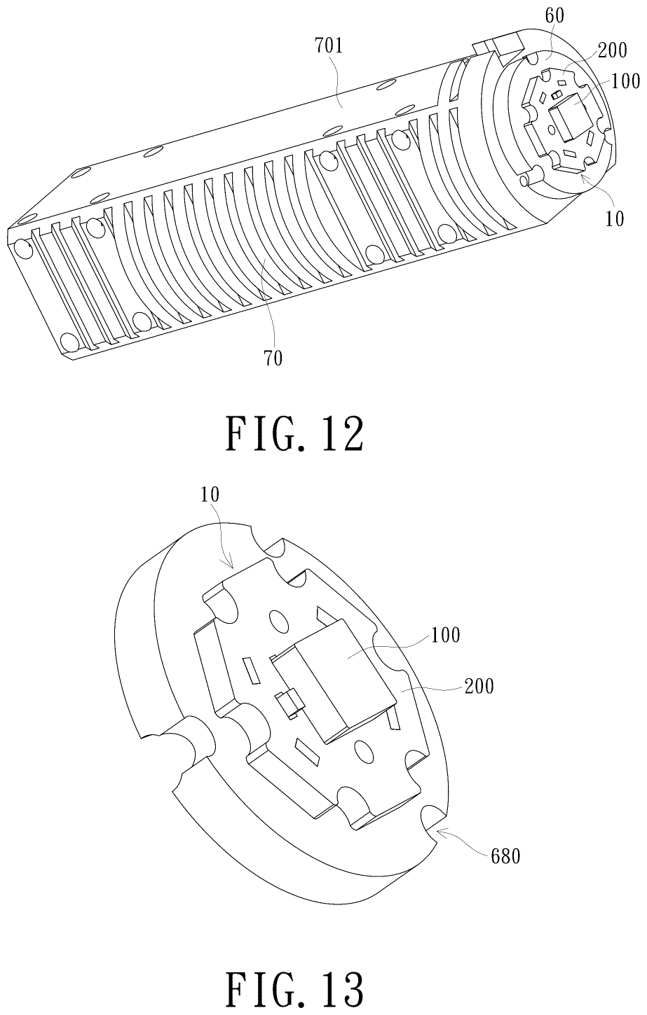

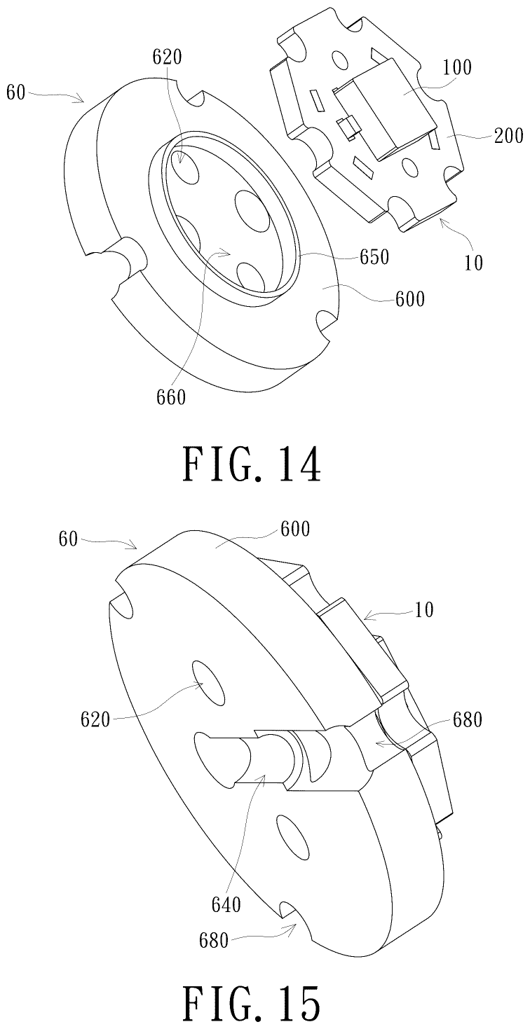

In a preferred embodiment of the disclosure, a material of the heat dissipation member 70 is at least a high-thermal-conductivity material, and preferably red copper, and the light source heat dissipation structure 10 is arranged in contact with the heat dissipation member 70. Besides, the control board C may be further used for the control board C to be arranged thereon. FIG. 12 shows a schematic partial view of a light source device. As shown in FIG. 11 to FIG. 12, the heat dissipation member 70 may further have a platform portion 701, which is suitable for the control board C to be arranged thereon and can help heat dissipation of the control board C. FIG. 13 is a schematic partial view of FIG. 12, and FIG. 14 is a schematic exploded view of FIG. 13. As shown in FIG. 12 to FIG. 14, the light source device 1 preferably further includes a connecting member 60 arranged between the light source heat dissipation structure 10 and the heat dissipation member 70. The connecting member 60 is in contact with the heat dissipation member 70 and the light source heat dissipation structure 10, so that heat energy of the light source heat dissipation structure 10 can be effectively conducted to the heat dissipation member 70 and the light-emitting component 100 can be maintained in an appropriate temperature range.

As shown in FIG. 14, the connecting member 60 includes a plate body 600 and an annular seat body 650, and the annular seat body 650 is arranged on the plate body 600. An accommodating space 660 is formed between an inner side of the annular seat body 650 and the plate body 600. The light source heat dissipation structure 10 is further arranged in contact with the annular seat body 650, and the carrying plate 200 may cover the accommodating space 660. In a preferred embodiment of the disclosure, a projection of the first region 2011 of the carrying surface 201 on the connecting member 60 is preferably included in the accommodating space 660. The accommodating space 660 may be used for, for example, receiving wires, for example, receiving wires of the external circuit connected to the pair of electrodes.

As shown in FIG. 14 to FIG. 15, the plate body 600 of the connecting member 60 is further formed with at least one via 620 and a slot portion 640. The via 620 runs through the plate body 600 and may be opened in the accommodating space 660, and is suitable for wires to pass through. For example, the wires of the external circuit connected to the pair of electrodes may pass through the via 620 and then be connected to the control board C. The via 620 may be in communication with the slot portion 640, but is not limited thereto. The slot portion 640 is located on opposite sides of the plate body 600 with the annular seat body 650. Preferably, the slot portion is elongated and extends to an edge of the plate body 600, and is suitable for accommodating wires, which can prevent the wires from protruding from the plate body 600 and affecting the flat attachment between the plate body 600 and the heat dissipation member 70. The connecting member 60 may further be formed with notches 680 at edges of the plate body 600. The notches 680 may be in communication with the slot portion 640, but are not limited thereto. The notches 680 may be used for wires to pass through and be received therein. In some examples of the disclosure, for example, the wires from the pair of electrodes may pass through the notches 260 at the edges of the carrying plate 200 and the notches 680 at the edges of the plate body 600 and then be connected to the control board C.

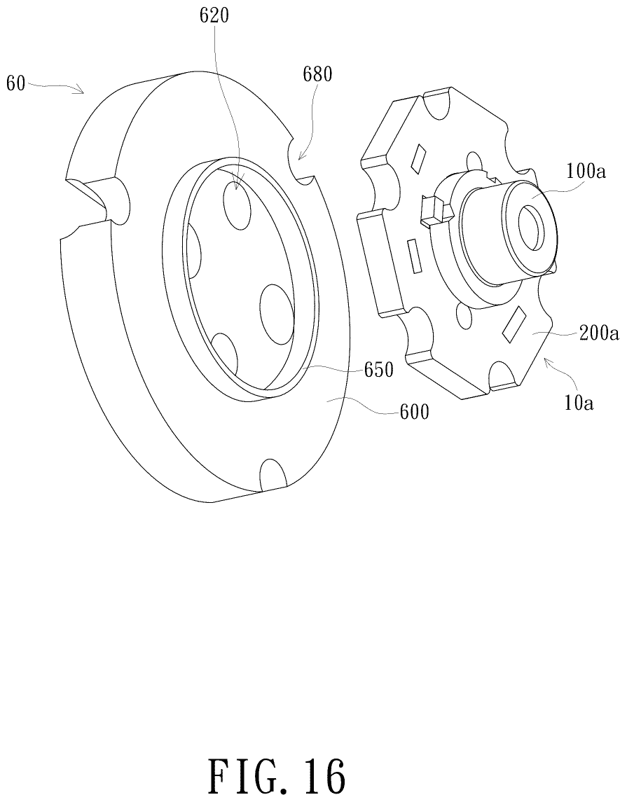

FIG. 16 is a schematic partial view of another light source device of the disclosure. The difference from the above embodiment is that the light source device 1 of FIG. 16 has the light source heat dissipation structure 100a. As described above, the light source structure 100a has the pair of leaded pins 120, and the pair of leaded pins 120 pass through the pair of socket holes 240 and may protrude from the opposite sides of the carrying surface 201, and are configured to be electrically connected to the external circuit. In this embodiment, the wires connected to the pair of leaded pins 120 may be connected to the control board C via the accommodating space 660 and the vias 620.

Based on the above, the light source heat dissipation structure 10 (10a) in the embodiments of the disclosure has the characteristics in material and structure. The material has the characteristic of ultrahigh thermal conductivity, so the light source heat dissipation structure 10 (10a) has good heat dissipation effectiveness and high heat dissipation efficiency. In structure, there is direct and effective contact between the light-emitting component 100 (100a) as a high heat generating source and the ultrahigh-thermal-conductivity material, including the arrangement of the light-emitting component 100 (100a) in contact with the carrying plate 200 (200a), the arrangement of the connecting member 60 in contact with the carrying plate 200 (200a) and the heat dissipation member 70, and the flat attachment between the connecting member 60 and the heat dissipation member 70; and the materials of the carrying plate 200 (200a), the connecting member 60 and the heat dissipation member 70 are respectively at least a material having ultrahigh thermal conductivity, which is more beneficial to improve the heat dissipation efficiency of the light source heat dissipation structure 10 (10a). Since the light source heat dissipation structure 10 (10a) has good heat dissipation effectiveness and heat dissipation efficiency, the temperature range of the light-emitting component 100 (100a) can be well controlled, which thus can provide reliable light output. Besides, due to good heat dissipation performance, the same or better heat dissipation effect can be achieved with a small volume, which is beneficial to miniaturization and lightweight of the light source device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light source heat dissipation structure, comprising:
a light-emitting component; and
a carrying plate, having a carrying surface, wherein the light-emitting component is arranged on the carrying surface, a material of the carrying plate is at least a high-thermal-conductivity material having a thermal conductivity of 380 W/mK or more, the high-thermal-conductivity material forms a first region on the carrying surface, and the light-emitting component is arranged in contact with the first region.

2. The light source heat dissipation structure according to claim 1, wherein the high-thermal-conductivity material is red copper.

3. The light source heat dissipation structure according to claim 1, further comprising a first pair of electrodes arranged on the carrying surface and electrically connected to the light-emitting component.

4. The light source heat dissipation structure according to claim 3, wherein the light-emitting component further comprises a pair of pins, and the light-emitting component is welded and fixed to the carrying plate through the pair of pins, and further electrically connected to the first pair of electrodes through the pair of pins.

5. The light source heat dissipation structure according to claim 3, further comprising a circuit board arranged on the carrying surface, wherein the circuit board comprises an insulating layer and a wiring layer that are stacked, and the first pair of electrodes are further arranged on the circuit board and connected to the wiring layer.

6. The light source heat dissipation structure according to claim 5, wherein the carrying surface further comprises a second region, the first region is located in a middle of the carrying surface, the second region surrounds the first region, and the circuit board is further arranged in the second region.

7. The light source heat dissipation structure according to claim 1, further comprising a thermally sensitive component and a second pair of electrodes arranged on the carrying surface, wherein the thermally sensitive component is electrically connected to the second pair of electrodes.

8. The light source heat dissipation structure according to claim 1, wherein the carrying plate is further formed with a pair of socket holes, the pair of socket holes run through the carrying plate and are opened in the first region and two opposite sides of the carrying surface, the light-emitting component further comprises a pair of leaded pins, and the pair of leaded pins pass through the pair of socket holes and protrude from the opposite sides of the carrying surface.

9. The light source heat dissipation structure according to claim 8, wherein an insulating layer is arranged in each of the pair of socket holes, and each of the pins is separated from a wall of the respective socket hole through the insulating layer.

10. The light source heat dissipation structure according to claim 1, wherein the carrying plate is further formed with at least one through hole, the at least one through hole runs through the carrying plate and is opened in the carrying surface and two opposite sides of the carrying surface, and the through hole is suitable for a wire to pass through.

11. The light source heat dissipation structure according to claim 1, wherein the light-emitting component is laser diodes.

12. A light source device, comprising:
a light source heat dissipation structure, comprising:
a light-emitting component; and
a carrying plate, having a carrying surface, wherein the light-emitting component is arranged on the carrying surface, a material of the carrying plate is at least a high-thermal-conductivity material having a thermal conductivity of 380 W/mK or more, the high-thermal-conductivity material forms a first region on the carrying surface, and the light-emitting component is arranged in contact with the first region;
a heat dissipation member, connected to the light source heat dissipation structure; and
a box, having a light exit hole, wherein the light source heat dissipation structure and the heat dissipation member are arranged in the box, and light generated by the light-emitting component is suitable to exit through the light exit hole.

13. The light source device according to claim 12, further comprising a connecting member, arranged between the light source heat dissipation structure and the heat dissipation member.

14. The light source device according to claim 13, wherein the connecting member comprises a plate body and an annular seat body, the annular seat body is arranged on the plate body, and an accommodating space is formed between an inner side of the annular seat body and the plate body.

15. The light source device according to claim 14, wherein the light source heat dissipation structure is further arranged in contact with the annular seat body, and the carrying plate covers the accommodating space.

16. The light source device according to claim 14, wherein the plate body is further formed with at least one via and a slot portion, the at least one via runs through the plate body and is opened in the accommodating space, the slot portion is located on two opposite sides of the plate body with the annular seat body, and the at least one via and the slot portion are suitable for a wire to pass through.

17. The light source device according to claim 12, further comprising a control board electrically connected to the light source heat dissipation structure, wherein the control board is suitable for controlling the light-emitting component to emit light.
